(19) United States
(12) Patent Application Publication
(10) Pub. No.: US 2026/0047137 A1
(43) Pub. Date: Feb. 12, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Yu KAO, Hsinchu (TW); Shih-Yao LIN, New Taipei City (TW); Chih-Han LIN, Hsinchu (TW); Ming-Ching CHANG, Hsinchu (TW); Chao-Cheng CHEN, Hsinchu (TW)

(21) Appl. No.: 18/797,708

(22) Filed: Aug. 8, 2024

(51) Int. Cl. H01L 29/423; H01L 21/306; H01L 21/3065; H01L 21/324; H01L 21/8234; H01L 29/06; H01L 29/66; H01L 29/775; H01L 29/786

(52) U.S. Cl. CPC H10D 30/6735; H01L 21/30608; H01L 21/3065; H01L 21/324; H10D 30/014; H10D 30/43; H10D 30/6757; H10D 62/121; H10D 64/017; H10D 84/013; H10D 84/0135; H10D 84/0151; H10D 84/038

(57) ABSTRACT

Embodiments of the present disclosure provide methods for forming semiconductor device structures. The method includes forming a fin structure from a substrate, and the fin structure includes alternating first and second semiconductor layers. The method further includes removing edge portions of each of the second semiconductor layers, depositing an insulating material around the fin structure, performing a thermal process to expand the second semiconductor layers laterally, forming a sacrificial gate structure over a portion of the fin structure, recessing an exposed portion of the fin structure, and forming a source/drain region over the recessed portion of the fin structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are perspective views of various stages of manufacturing a semiconductor device structure, in accordance with some embodiments.

FIGS. 3 and 4 are cross-sectional side views of various stages of manufacturing the semiconductor device structure, in accordance with some embodiments.

FIGS. 5-8 are perspective views of various stages of manufacturing the semiconductor device structure, in accordance with some embodiments.

FIGS. 9-18 are cross-sectional side views of the semiconductor device structure taken along line A-A of FIG. 8, in accordance with some embodiments.

FIG. 17-1 is an enlarged cross-section side view of a portion of the semiconductor device structure of FIG. 17, in accordance with some embodiments.

FIG. 19 is a cross-sectional top view of the semiconductor device structure taken along line B-B of FIG. 18, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a method to form a semiconductor device structure. The method includes forming a fin structure having alternately stacked first and second semiconductor layers and removing edge portions of the second semiconductor layers. During the subsequent process to form isolation regions, the second semiconductor layers expend laterally, so side surfaces of the second semiconductor layers and side surfaces of the first semiconductor layers are substantially co-planar. As a result, gate electrode layer defects and electrical short between the gate electrode layer and the source/drain region are reduced.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

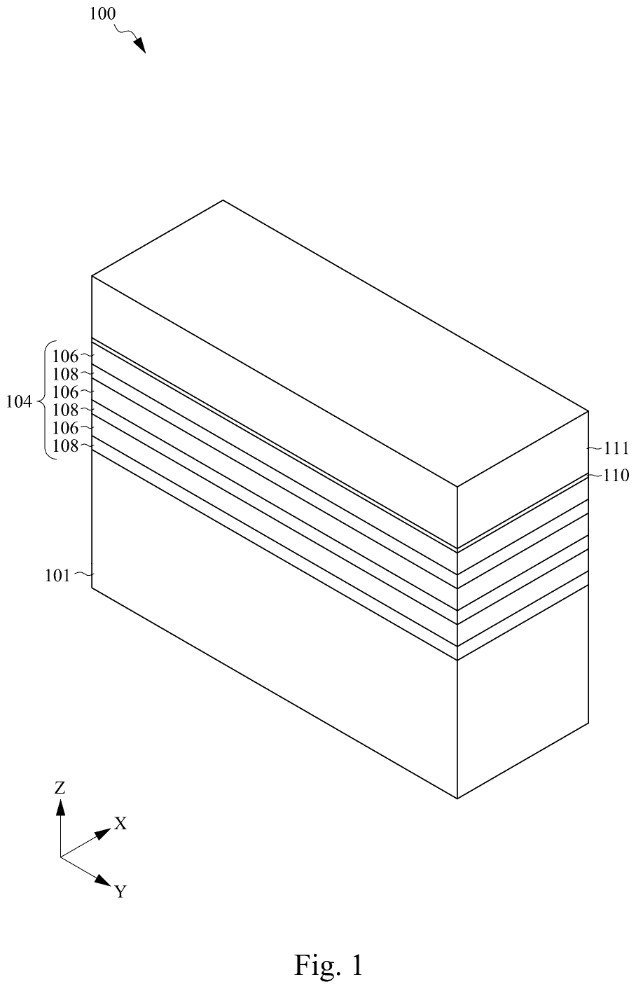

FIGS. 1-19 show exemplary processes for manufacturing a semiconductor device structure 100 according to embodiments of the present disclosure. It is understood that additional operations can be provided before, during, and after processes shown by FIGS. 1-19, and some of the operations described below can be replaced or eliminated, for additional embodiments of the method. The order of the operations/processes is not limiting and may be interchangeable.

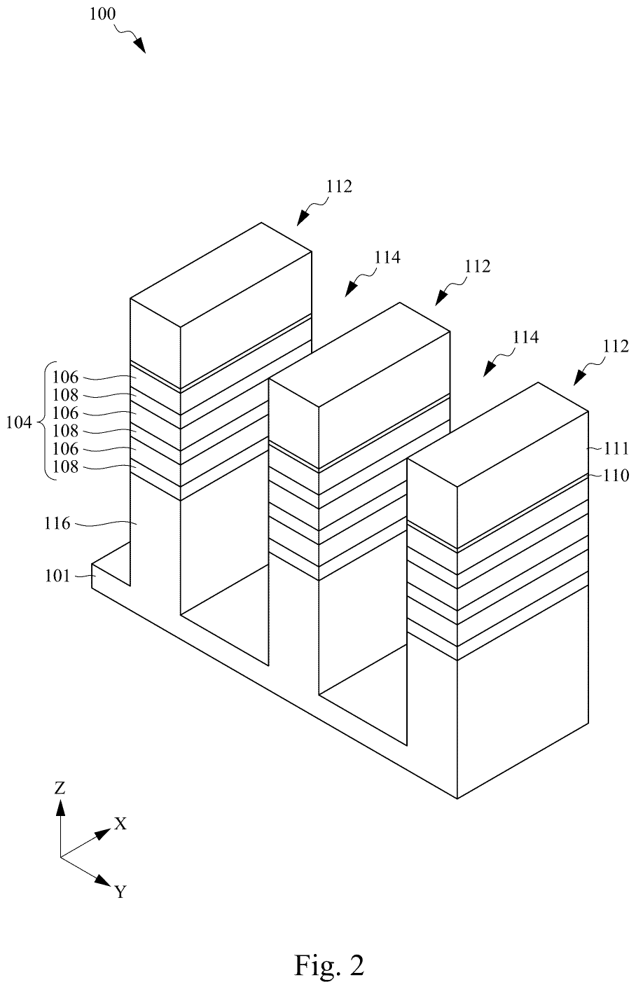

FIGS. 1 and 2 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

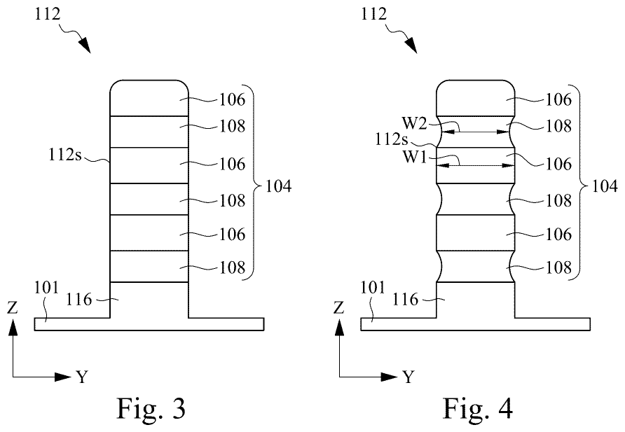

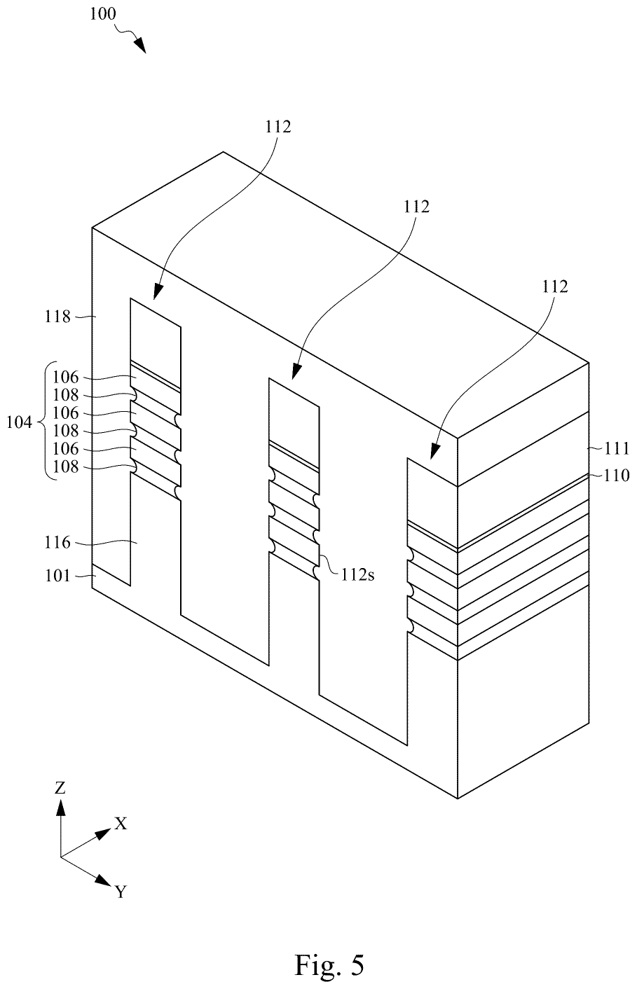

FIGS. 3 and 4 are cross-sectional side views of various stages of manufacturing the semiconductor device structure 100, in accordance with some embodiments. The oxide layer 110 and the nitride layer 111 are omitted in FIGS. 3 and 4 for clarity. FIG. 3 illustrates the fin structure 112 of FIG. 2. As shown in FIG. 3, in some embodiments, the fin structure 112 includes a side surface 112s that is substantially planar as a result of the etching process described above. In other words, in some embodiments, side surfaces of the first semiconductor layers 106 and side surfaces of the second semiconductor layers 108 are substantially co-planar.

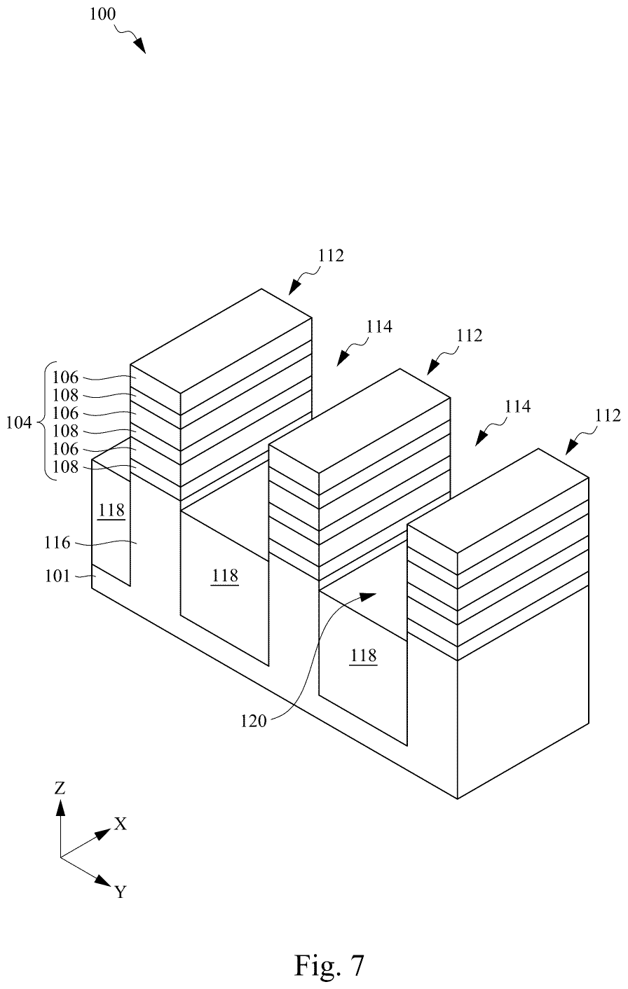

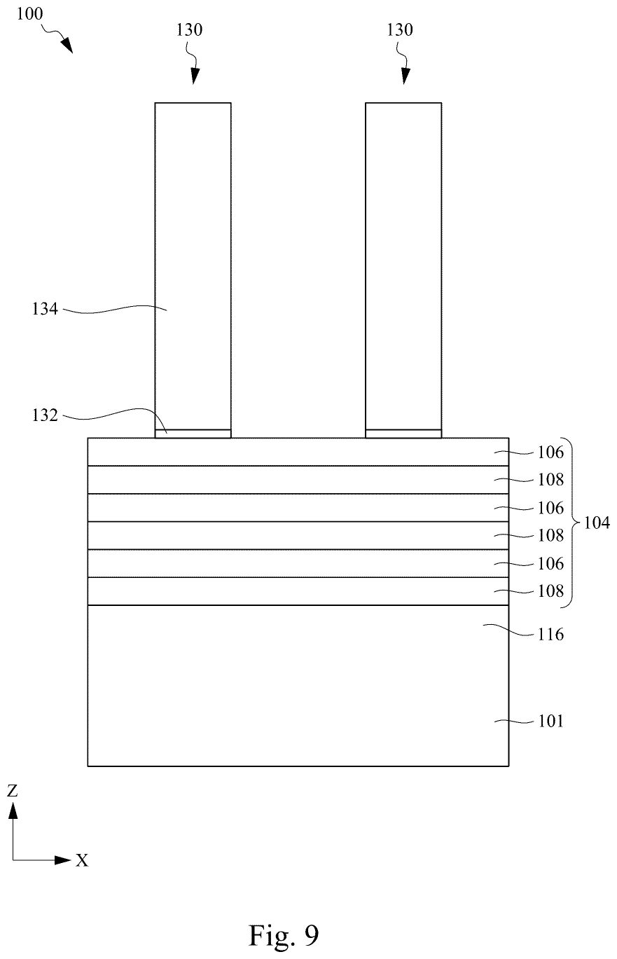

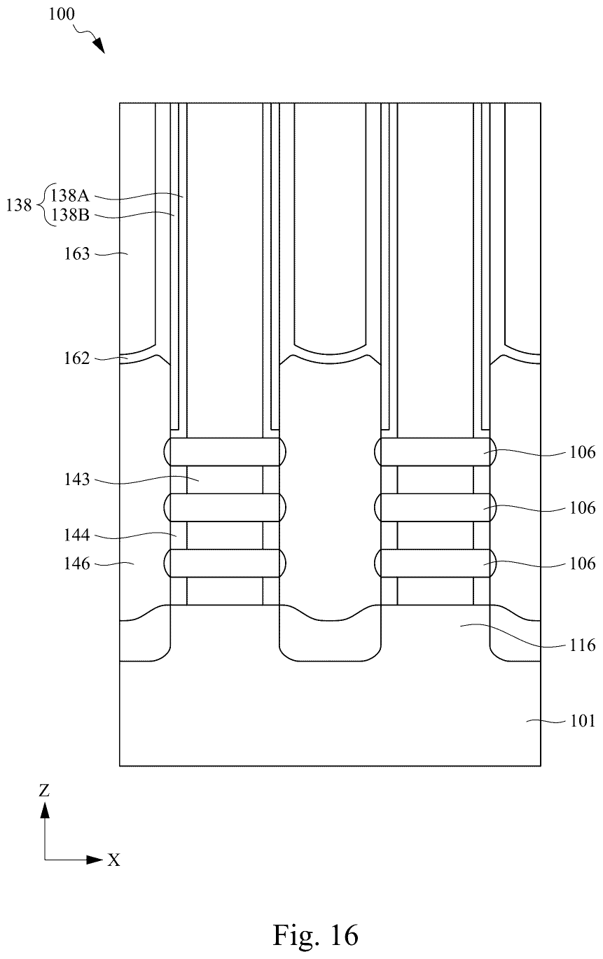

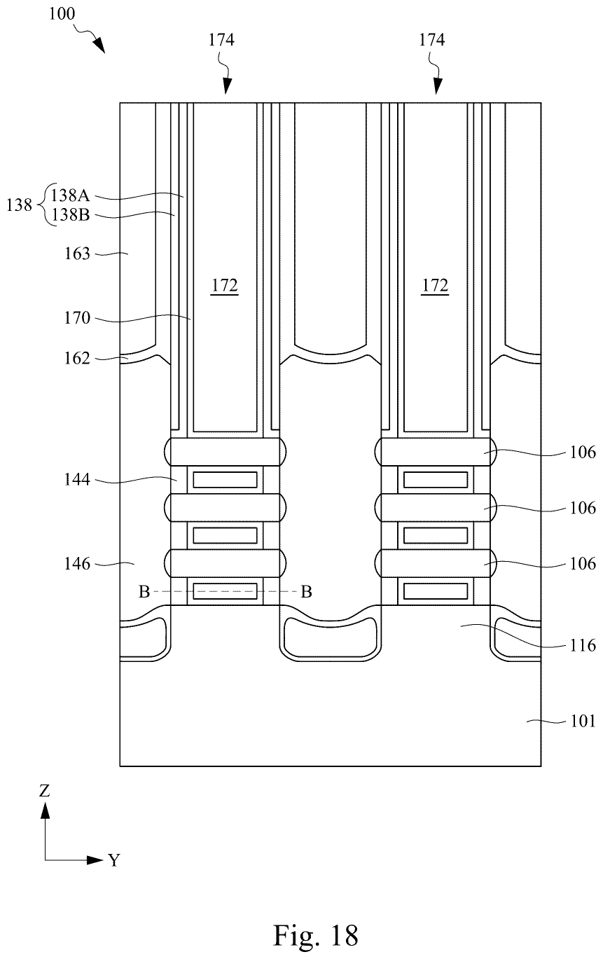

In some embodiments, subsequent processes to form isolation regions 120 (FIG. 6) may include a thermal process which causes the second semiconductor layers 108 to expand laterally (along the Y direction). As a result, the side surface 112s of the fin structure 112 would include protrusions from the second semiconductor layers 108, which can lead to residue formed on side surface of a subsequently formed sacrificial gate electrode layer 134 (FIG. 8). The residue can lead to defects in the subsequently formed gate electrode layer 172 (FIG. 18), which can cause electrical short between the gate electrode layer 172 and the source/drain region 146 (FIG. 15). Thus, in some embodiments, in order to reduce the defects in the gate electrode layer 172 and to reduce the risk of electrical short between the gate electrode layer 172 and the source/drain region 146, edge portions of the second semiconductor layers 108 may be removed, as shown in FIG. 4.

The edge portions of the second semiconductor layers 108 are removed by any suitable process. In some embodiments, a selective etch process is performed to remove the edge portions of the second semiconductor layers 108, while the first semiconductor layers 106 are not substantially affected. The selective etch process may be a plasma etch process. In some embodiments, the plasma etch process utilizes one or more etchants such as CH₄, CHF₃, HBr, Cl₂, and/or H₂. One or more passivation gases, such as N₂ and/or O₂, may be also used in the plasma etch process to improve selectivity. The plasma etch process may also utilize dilute gas, such as Ar, He, or N₂. The flow rate of the gases may range from about 20 standard cubic centimeter per minute (sccm) to about 3000 sccm. The plasma power of the plasma etch process may range from about 10 W to about 4000 W, and the chamber pressure of the plasma etch process may range from about 1 mTorr to about 800 mTorr.

In some embodiments, an isotropic selective etch process may be performed to remove the edge portions of the second semiconductor layers 108. In some embodiments, the isotropic selective etch process is a wet etch process. In cases where the second semiconductor layers 108 are made of SiGe and the first semiconductor layers 106 are made of silicon, the wet etch process may use a wet etchant such as, but not limited to, ammonium hydroxide (NH₄OH), tetramethylammonium hydroxide (TMAH), ethylenediamine pyrocatechol (EDP), or potassium hydroxide (KOH) solutions.

In some embodiments, the side surface of the second semiconductor layer 108 is curved as a result of the removal of the edge portions of the second semiconductor layer 108, as shown in FIG. 4. In some embodiments, the side surface of the second semiconductor layer 108 has a concave profile. Each side surface of the first semiconductor layers 106 is substantially flat, as shown in FIG. 4. Thus, in some embodiments, the side surface 112s of the fin structure 112 includes alternating flat and concave surfaces, as shown in FIG. 4.

As shown in FIG. 4, each of the first semiconductor layers 106 has a first width W1 along the Y direction, and each of the second semiconductor layers 108 has a second width W2 along the Y direction. In some embodiments, because of the concave side surfaces, the second width W2 of the second semiconductor layer 108 is not constant. For example, the width W2 of a second semiconductor layer 108 increases in directions toward the first semiconductor layers 106 disposed above and below the second semiconductor layer 108. Thus, in some embodiments, the width W2 is the smallest in the center of the second semiconductor layer 108 along the Z direction. The smallest W2 is less than the constant width W1 and may be about five percent to about 20 percent less than the constant width W1.

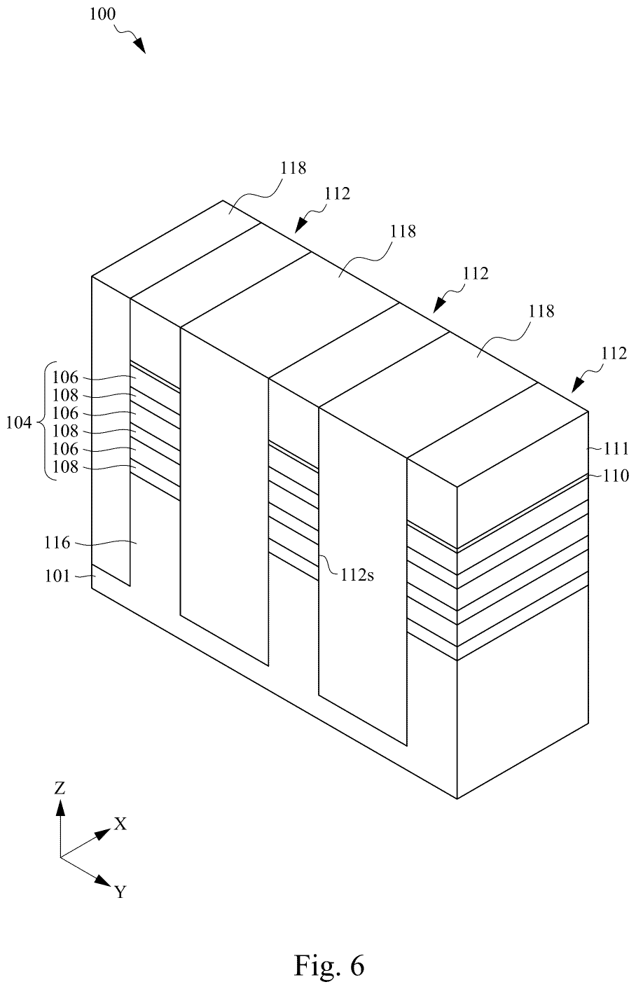

FIGS. 5-8 are perspective views of various stages of manufacturing the semiconductor device structure 100, in accordance with some embodiments. As shown in FIG. 5, after the removal of the edge portions of the second semiconductor layers 108, an insulating material 118 is deposited on the substrate 101. The insulating material 118 fills the trenches 114 between neighboring fin structures 112 until the fin structures 112 are embedded in the insulating material 118, as shown in FIG. 5. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

In some embodiments, after the deposition of the insulating material 118, a thermal process is performed to improve the quality of the insulating material 118. In some embodiments, the thermal process is an annealing process with a high processing temperature ranging from about 500 degrees Celsius to about 700 degrees Celsius. The annealing process with high processing temperature can also cause the second semiconductor layers 108 to expand laterally along the Y direction. As a result of the thermal process, the side surfaces of the first and second semiconductor layers 106, 108 may be substantially co-planar, as shown in FIG. 6. The thermal process may densify the insulating material 118. The expanding second semiconductor layers 108 may further densify the insulating material 118 by pushing out the portions of the insulating material 118 located in the recesses created by the removal of the edge portions of the second semiconductor layers 108.

In some embodiments, the thermal process to improve the quality of the insulating material 118 is performed with a low processing temperature of less than about 400 degrees Celsius, such as from about 300 degrees Celsius to about 380 degrees Celsius. At a processing temperature of less than about 400 degrees Celsius, the second semiconductor layers 108 would not expand laterally. Thus, in some embodiments, the edge portions of the second semiconductor layers 108 are not removed after the formation of the fin structures 112, and the annealing process performed after the deposition of the insulating material 118 has a processing temperature of less than about 400 degrees Celsius. In other words, with the low processing temperature to anneal the insulating material 118, the processes described in FIG. 4 may be omitted.

Next, as shown in FIG. 6, a planarization operation, such as a chemical mechanical polishing (CMP) method and/or an etch-back method, is performed such that the top of the fin structures 112 is exposed.

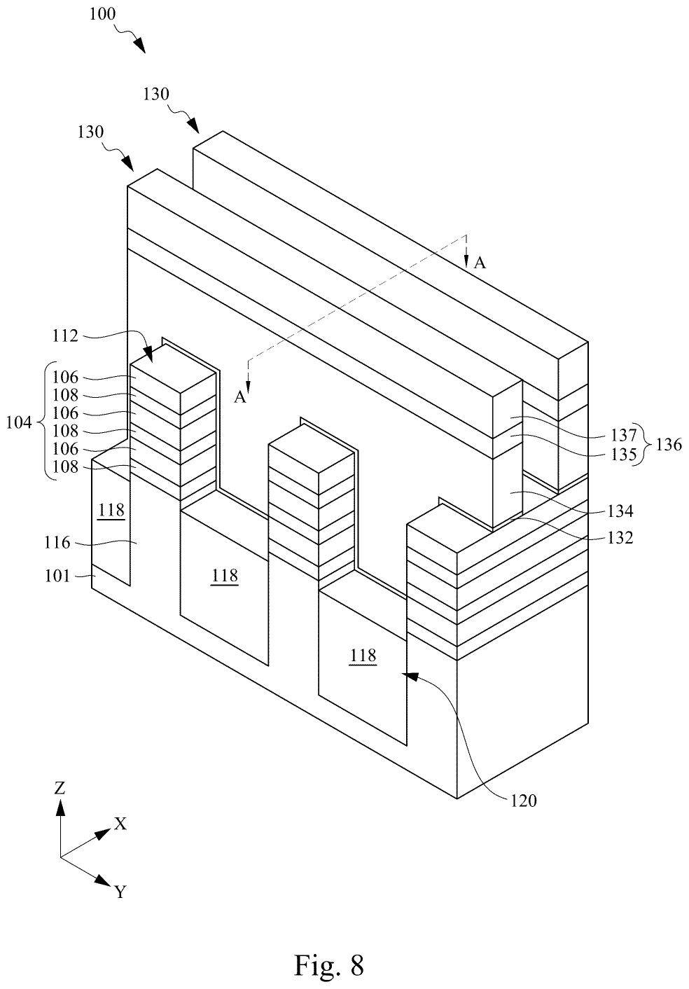

In FIG. 7, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

In FIG. 8, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

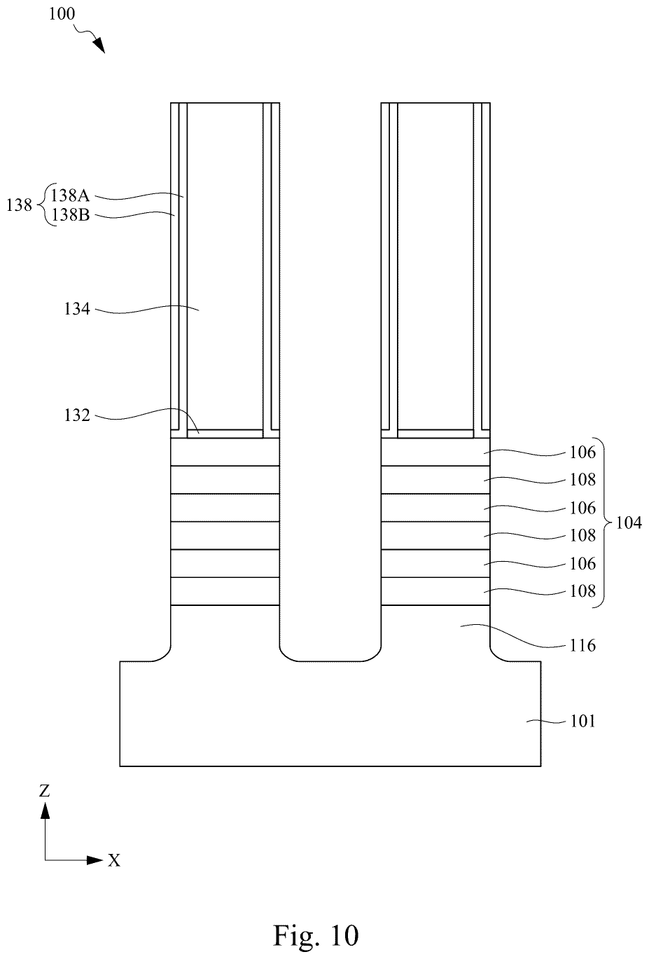

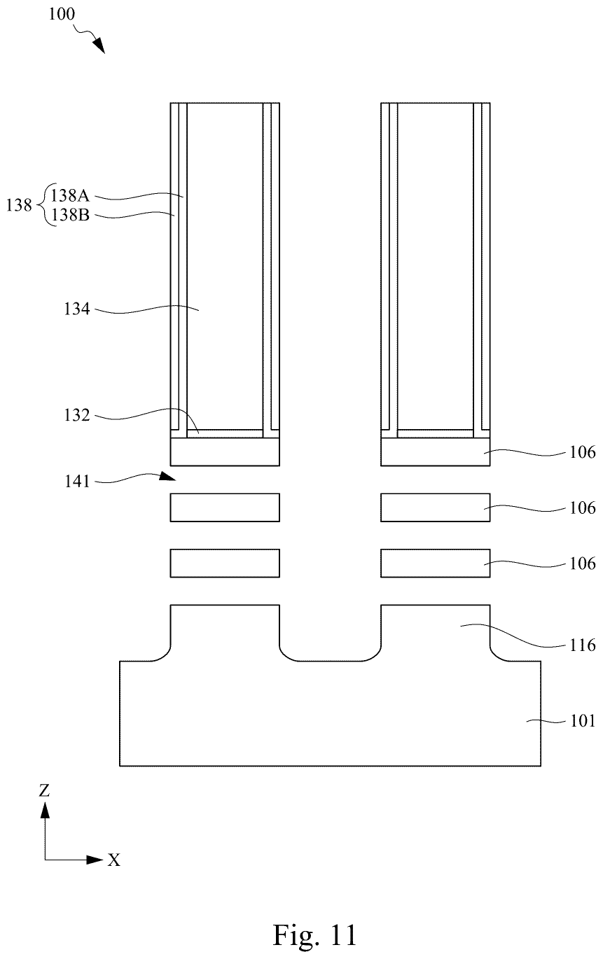

FIGS. 9-18 are cross-sectional side views of the semiconductor device structure 100 taken along line A-A of FIG. 8, in accordance with some embodiments. As shown in FIG. 9, the sacrificial gate structures 130 includes the sacrificial gate dielectric layer 132 and the sacrificial gate electrode layer 134, and the mask layer 136 is omitted for clarity. Next, as shown in FIG. 10, gate spacers 138 are formed on sidewalls of the sacrificial gate structures 130. The gate spacers 138 may be formed by conformally depositing one or more layers, such as first gate spacer 138A and second gate spacer 138B, as shown in FIG. 10, and then anisotropic etching the one or more layers, for example. The gate spacers 138A, 138B may be made of a dielectric material such as silicon oxide, silicon nitride, silicon carbide, silicon oxynitride, SiCN, silicon oxycarbide, SiOCN, and/or combinations thereof.

As shown in FIG. 10, the second portions of the fin structures 112 not covered by the sacrificial gate structure 130 and the gate spacers 138 are recessed to a level above, at, or below the top surfaces of the isolation regions 120 (FIG. 8). The recessing of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

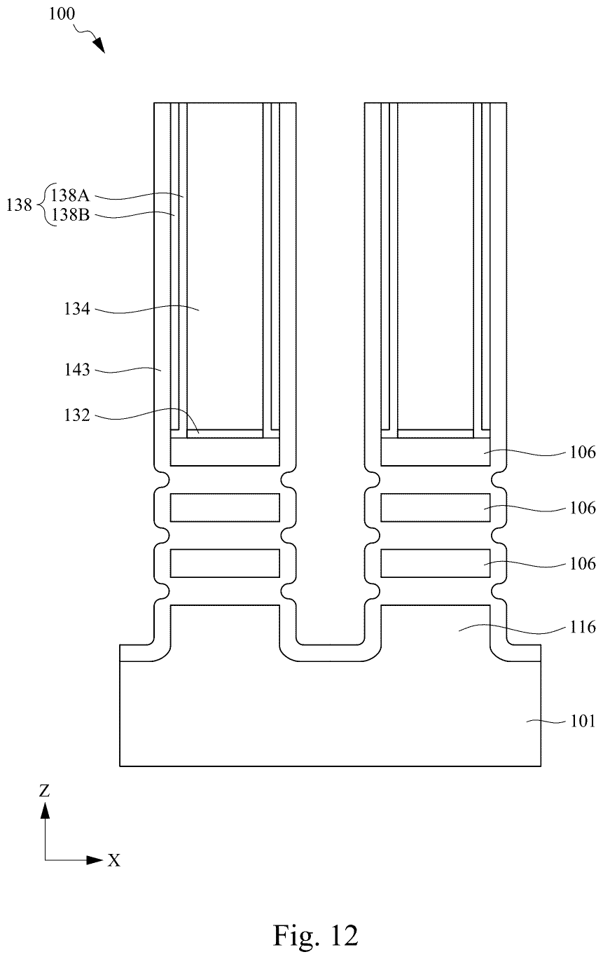

Next, as shown in FIG. 11, the second semiconductor layers 108 are removed. The second semiconductor layers 108 may be removed by a selective etch process, such as a selective dry etch process, a selective wet etch process, or a combination thereof. In some embodiments, due to the open space around the first semiconductor layers 106, the etchant of the selective etch process does not substantially affect the first semiconductor layers 106. The removal of the second semiconductor layers 108 form openings 141 between vertically adjacent first semiconductor layers 106, as shown in FIG. 11.

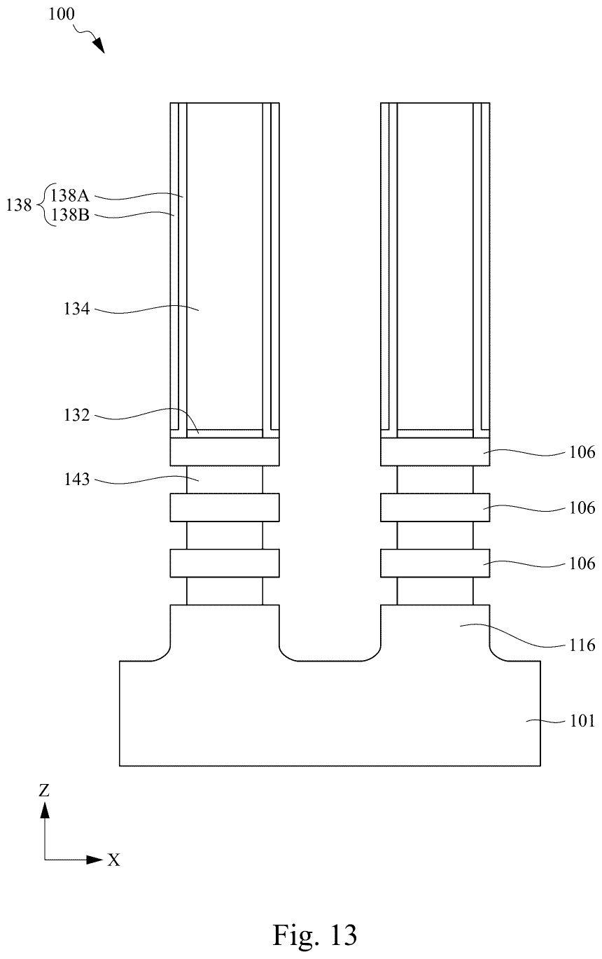

In FIG. 12, a dielectric material 143 is formed in the openings 141 and on the exposed surfaces of the semiconductor device structure 100. In some embodiments, the dielectric material 143 is an oxide formed by any suitable process, such as ALD, CVD, PECVD, or FCVD. In some embodiments, the oxide is a carbon-containing silicon oxide.

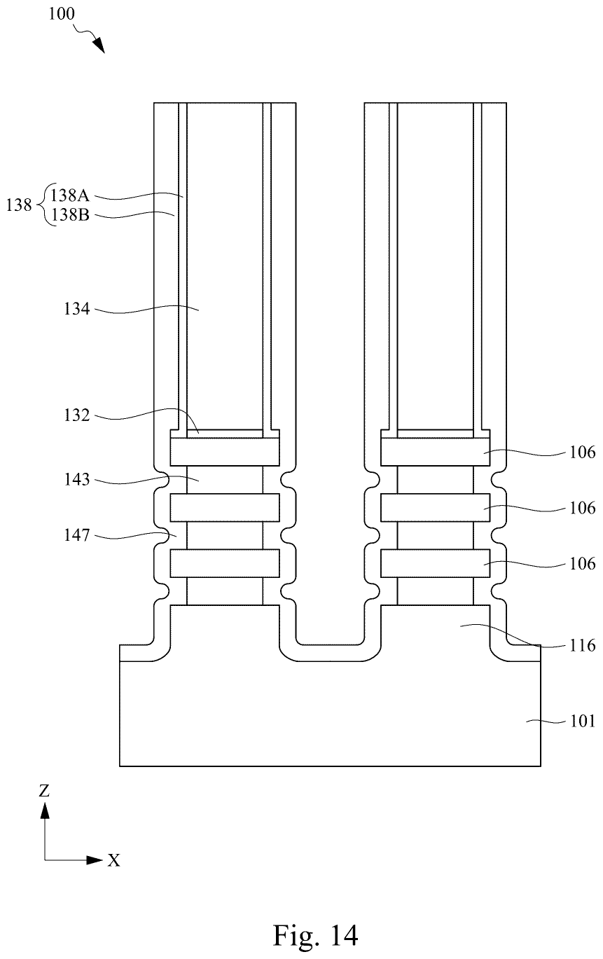

In FIG. 13, an etch back process is performed to remove portions of the dielectric material 143 other than the portions of the dielectric material 143 formed in the openings 141. In some embodiments, the etch back process is an anisotropic etching process. At this stage, edge portions of the dielectric material 143 and edge portions of the first semiconductor layers 106 have substantially flat surfaces which may be flush with side surfaces of the gate spacers 138. Next, as shown in FIG. 13, edge portions of the dielectric material 143 are removed horizontally along the X direction. In other words, the dielectric material 143 is recessed along the X direction. The removal of the edge portions of the dielectric material 143 forms cavities. In some embodiments, the edge portions of the dielectric material 143 are removed by a selective wet etch process.

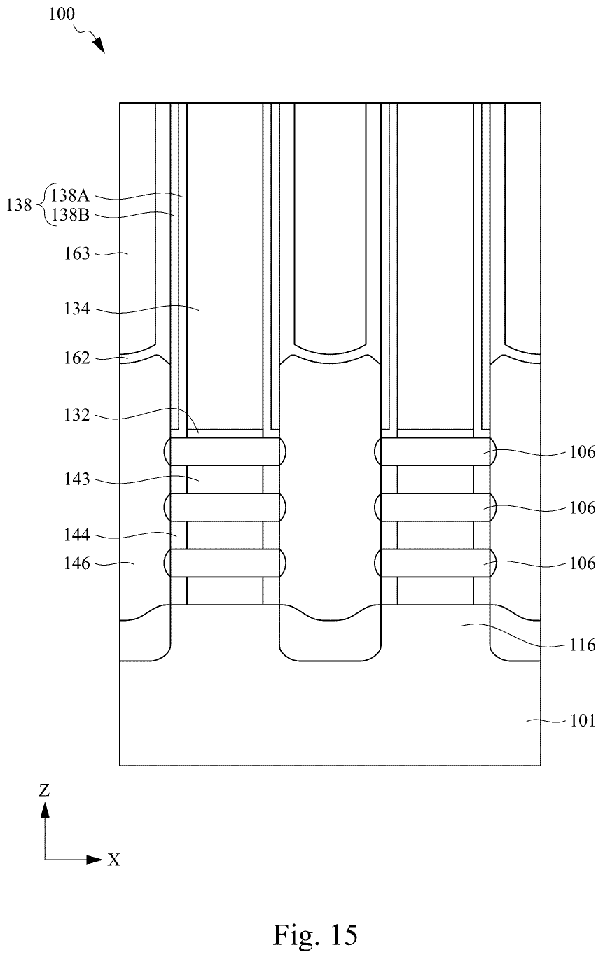

In FIG. 14, after removing the edge portions of the dielectric material 143, a dielectric layer 147 is deposited in the cavities. The dielectric layer 147 may be made of a dielectric material, such as SiON, SiCN, SiOC, SiOCN, or SiN. The dielectric layer 147 may be formed by a conformal deposition process, such as ALD.

In FIG. 15, dielectric spacers 144 are formed by removing portions of the dielectric layer 147. In some embodiments, the portions of the dielectric layer 147 are removed by an anisotropic etching process. The dielectric spacers 144 are protected by the first semiconductor layers 106 during the anisotropic etching process. The dielectric material 143 is capped between the dielectric spacers 144 along the X direction, as shown in FIG. 15. In some embodiments, the dielectric spacers 144 and the dielectric material 143 include different materials having different etch selectivity.

Next, as shown in FIG. 15, source/drain (S/D) regions 146 are formed over the substrate 101. In some embodiments, the S/D regions 146 may grow both vertically and horizontally to form facets, which may correspond to crystalline planes of the material used for the substrate 101. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146 are n-type S/D epitaxial features and may be made of one or more layers of Si, SiP, SiC and SiCP for n-channel FETs. In some embodiments, the S/D regions 146 are p-type epitaxial features and may be made of one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. The S/D region 146 may include doped and undoped epitaxial materials.

Next, a contact etch stop layer (CESL) 162 is conformally formed on the exposed surfaces of the semiconductor device structure 100, as shown in FIG. 15. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 15. The planarization process may be any suitable process, such as a CMP process. The planarization process removes portions of the ILD layer 163 and the CESL 162 disposed on the sacrificial gate structures 130. The planarization process may also remove the mask layer 136 (FIG. 8).

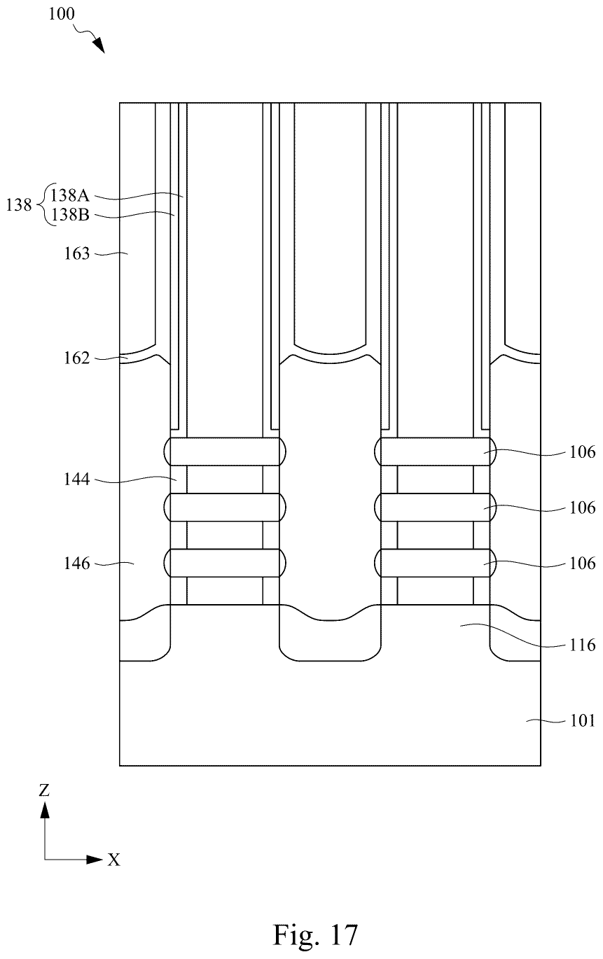

In FIG. 16, the sacrificial gate electrode layer 134 and the sacrificial gate dielectric layer 132 are removed, exposing a portion of the top surface of the topmost first semiconductor layer 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 163, and the CESL 162.

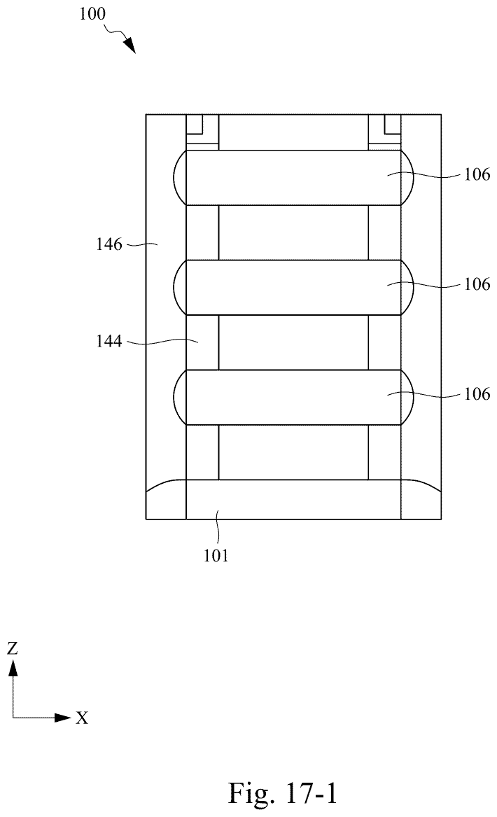

In FIG. 17, the dielectric material 143 is removed. The dielectric material 143 may be removed by any suitable process. In some embodiments, the dielectric material 143 is removed by a selective etch process. The selective etch process removes the dielectric material 143 between the first semiconductor layers 106 but does not remove the first semiconductor layers 106, the ILD layer 163, the CESL 162, and the gate spacers 138. The portion of each first semiconductor layer 106 not covered by the dielectric spacers 144 may be exposed after the removal of the dielectric material 143. Each first semiconductor layer 106 may be a nanostructure channel.

FIG. 17-1 is an enlarged cross-section side view of a portion of the semiconductor device structure 100 of FIG. 17, in accordance with some embodiments. In some embodiments, the selective etch process to remove the dielectric material 143 does not substantially affect the semiconductor material of the first semiconductor layer 106. As a result, the thickness of the first semiconductor layer 106 along the Z direction is not substantially affected. For example, the thickness of the first semiconductor layer 106 may be reduced by less than about 0.5 nm as a result of the selective etch process to remove the dielectric material 143. The remaining thickness of the first semiconductor layer 106 may range from about 9 nm to about 10 nm. In some embodiments, the vertical distance between the vertically adjacent first semiconductor layers 106 may range from about 5 nm to about 6 nm. In some embodiments, as shown in FIG. 17-1, the top and bottom surfaces of the first semiconductor layer 106 are substantially flat.

In some embodiments, the second semiconductor layers 108 are not replaced with the dielectric material 143, and the second semiconductor layers 108 are removed after the removal of the sacrificial gate dielectric layer 132 and the sacrificial gate electrode layer 134. An etch process to remove the second semiconductor layers 108 may also remove portions of the first semiconductor layers 106 due to restricted spacing (i.e., the dielectric spacers 144 limits the flow of the etchant). As a result, the top and bottom surfaces of the first semiconductor layer 106 are recessed and may have a concave profile.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170, as shown in FIG. 18. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 163. The gate dielectric layer 170 and the gate electrode layer 172 formed over the ILD layer 163 are then removed by using, for example, CMP, until the top surface of the ILD layer 163 is exposed.

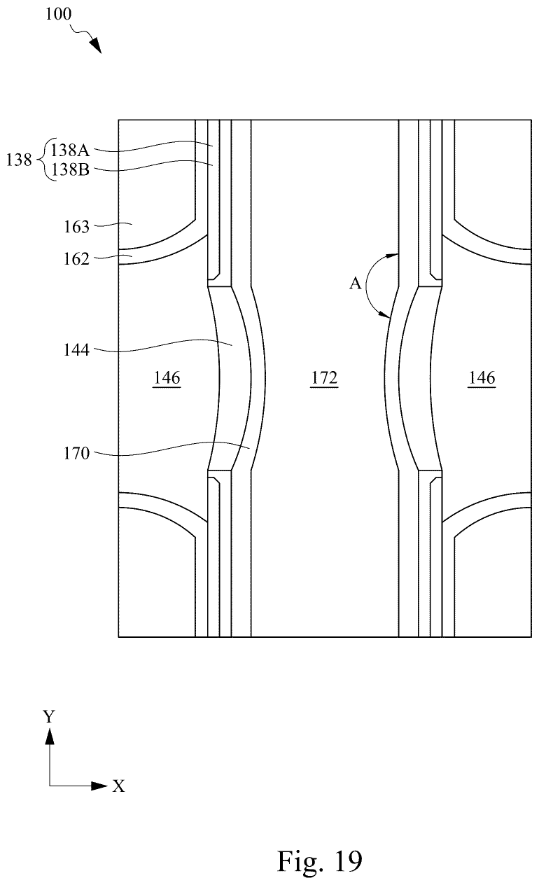

FIG. 19 is a cross-sectional top view of the semiconductor device structure 100 taken along line B-B of FIG. 18, in accordance with some embodiments. As shown in FIG. 19, the gate dielectric layer 170 and the S/D region 146 are separated by the gate spacer 138 and the dielectric spacer 144. In some embodiments, the thickness of the gate spacer 138 (the combined thickness of the first and second gate spacers 138A, 138B) may range from about 5 nm to about 10 nm, and the thickness of the dielectric spacer 144 may be the same as the thickness of the gate spacer 138. With such thick dielectric materials between the gate dielectric layer 170 and the S/D region 146, the risk of electrical short between the gate electrode layer 172 and the S/D region 146 is reduced. The thick gate spacer 138 may be a result of minimized residue formed on the side surfaces of the sacrificial gate electrode layer 134.

In addition, because the gate spacer 138 is in contact with the dielectric spacer 144, which is also a result of minimized residue formed on the side surfaces of the sacrificial gate electrode layer 134, the process window for removing the sacrificial gate structure 130 may be enlarged. For example, when removing the sacrificial gate electrode layer 134 and the dielectric material 143, the risk of exposing the S/D regions 146 is reduced. In some embodiments, the gate dielectric layer 170 includes a first portion located adjacent the gate spacer 138 and a second portion located adjacent the dielectric spacer 144. An angle A may be formed between the first and second portions of the gate dielectric layer 170, as shown in FIG. 19. In some embodiments, the angle A ranges from about 150 degrees to about 180 degrees. The angle A may be different depending on the location. In some embodiments, the angle A located below the bottom first semiconductor layer 106 ranges from about 150 degrees to about 165 degrees, the angle A located between the bottom first semiconductor layer 106 and the middle first semiconductor layer 106 ranges from about 165 degrees to about 170 degrees, and the angle A located between the middle first semiconductor layer 106 and the top first semiconductor layer 106 ranges from about 170 degrees to about 180 degrees.

Embodiments of the present disclosure provide methods for forming semiconductor device structure 100. The methods includes forming a fin structure 112 including alternating first and second semiconductor layers 106, 108, laterally recessing the second semiconductor layers 108, depositing an insulating material 118, and performing a thermal process to improve the quality of the insulating material 118 and to expand the second semiconductor layers 108 laterally. The expansion of the second semiconductor layers 108 may lead to planar side surfaces 112s of the fin structure 112. Some embodiments may achieve advantages. For example, the planar side surfaces 112s of the fin structure 112 can minimize the amount of residue formed in the corners of the sacrificial gate electrode layer 134. In some embodiments, the size of the residue formed in the corners of the sacrificial gate electrode layer 134 is less than about 4 nm, such as from about 1 nm to about 3 nm. The minimized residue can lead to enlarged process window for removing the sacrificial gate structure 130. Furthermore, the risk of electrical short between the gate electrode layer 172 and the S/D region 146 is reduced.

An embodiment is a method for forming a semiconductor device structure. The method includes forming a fin structure from a substrate, and the fin structure includes alternating first and second semiconductor layers. The method further includes removing edge portions of each of the second semiconductor layers, depositing an insulating material around the fin structure, performing a thermal process to expand the second semiconductor layers laterally, forming a sacrificial gate structure over a portion of the fin structure, recessing an exposed portion of the fin structure, and forming a source/drain region over the recessed portion of the fin structure.

Another embodiment is a method. The method includes forming a fin structure from a substrate, and the fin structure comprises alternating first and second semiconductor layers. The method further includes depositing an insulating material around the fin structure, performing a thermal process on the insulating material, and a processing temperature of the thermal process ranges from about 300 degrees Celsius to about 380 degrees Celsius. The method further includes forming a sacrificial gate structure over a portion of the fin structure, recessing an exposed portion of the fin structure, removing the second semiconductor layers to form openings between adjacent first semiconductor layers, and depositing a dielectric material in the openings.

A further embodiment is a method. The method includes forming a fin structure from a substrate, and the fin structure comprises a side surface having alternating flat and concave surfaces. The method further includes forming an isolation region around at least a portion of the fin structure, and the side surface of the fin structure becomes substantially planar during the formation of the isolation region. The method further includes forming a sacrificial gate structure over a portion of the fin structure, recessing an exposed portion of the fin structure, and forming a source/drain region over the recessed portion of the fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device structure, comprising:
forming a fin structure from a substrate, wherein the fin structure comprises alternating first and second semiconductor layers;
removing edge portions of each of the second semiconductor layers;
depositing an insulating material around the fin structure;
performing a thermal process to expand the second semiconductor layers laterally;
forming a sacrificial gate structure over a portion of the fin structure;
recessing an exposed portion of the fin structure; and
forming a source/drain region over the recessed portion of the fin structure.

2. The method of claim 1, wherein the thermal process is an annealing process.

3. The method of claim 2, wherein a processing temperature of the annealing process ranges from about 500 degrees Celsius to about 700 degrees Celsius.

4. The method of claim 1, wherein the edge portions of each of the second semiconductor layers are removed by a selective etch process.

5. The method of claim 4, wherein the selective etch process is an isotropic etch process.

6. The method of claim 4, wherein the selective etch process is a plasma etch process.

7. The method of claim 6, wherein the plasma etch process utilizes one or more etchants comprising CH₄, CHF₃, HBr, Cl₂, or H₂.

8. The method of claim 6, wherein a plasma power of the plasma etch process ranges from about 10 W to about 4000 W, and a chamber pressure of the plasma etch process ranges from about 1 mTorr to about 800 mTorr.

9. A method for forming a semiconductor device structure, comprising:
forming a fin structure from a substrate, wherein the fin structure comprises alternating first and second semiconductor layers;
depositing an insulating material around the fin structure;
performing a thermal process on the insulating material, wherein a processing temperature of the thermal process ranges from about 300 degrees Celsius to about 380 degrees Celsius;
forming a sacrificial gate structure over a portion of the fin structure;
recessing an exposed portion of the fin structure;
removing the second semiconductor layers to form openings between adjacent first semiconductor layers; and
depositing a dielectric material in the openings.

10. The method of claim 9, further comprising removing portions of the dielectric material to form cavities between adjacent first semiconductor layers.

11. The method of claim 10, further comprising forming dielectric spacers in the cavities.

12. The method of claim 11, further comprising removing the sacrificial gate structure.

13. The method of claim 12, further comprising removing the dielectric material after the removal of the sacrificial gate structure.

14. The method of claim 13, further comprising forming a gate structure between adjacent first semiconductor layers.

15. The method of claim 12, wherein the removal of the dielectric material is performed by an etch process, and the etch process reduces a thickness of the first semiconductor layers by about 1 nm to about 3 nm.

16. A method for forming a semiconductor device structure, comprising:
forming a fin structure from a substrate, wherein the fin structure comprises a side surface having alternating flat and concave surfaces;
forming an isolation region around at least a portion of the fin structure, wherein the side surface of the fin structure becomes substantially planar during the formation of the isolation region;
forming a sacrificial gate structure over a portion of the fin structure;
recessing an exposed portion of the fin structure; and
forming a source/drain region over the recessed portion of the fin structure.

17. The method of claim 16, wherein the fin structure further comprises alternating first and second semiconductor layers.

18. The method of claim 17, wherein side surfaces of the first semiconductor layers are substantially flat, and side surfaces of the second semiconductor layers have concave profiles prior to the formation of the isolation region.

19. The method of claim 18, wherein the side surfaces of the first and second semiconductor layers are substantially co-planar after the formation of the isolation region.

20. The method of claim 16, wherein the formation of the isolation region comprises a thermal process having a processing temperature ranging from about 500 degrees Celsius to about 700 degrees Celsius.
